(19) United States
(12) Patent Application Publication
(10) Pub. No.: US 2011/0062545 A1
(43) Pub. Date: Mar. 17, 2011

(54) SEMICONDUCTOR DEVICE AND ITS MANUFACTURING METHOD

(75) Inventor: Kouji NAKAJIMA, Kanagawa (JP)

(73) Assignee: RENESAS ELECTRONICS CORPORATION, Kanagawa (JP)

(21) Appl. No.: 12/884,448

(22) Filed: Sep. 17, 2010

(30) Foreign Application Priority Data
Sep. 17, 2009 (JP) 2009-215270

(51) Int. Cl. H01L 29/66; H01L 21/04

(52) U.S. Cl. 257/470; 438/54; 257/E29.347; 257/E21.04

(57) ABSTRACT

A semiconductor device in accordance with the present invention includes a diode 7 that is formed on a semiconductor substrate and serves as a temperature detection element to detect abnormal heat generation, and a thermal conduction layer 102 that is formed between the diode 7 and the semiconductor substrate and has a thermal conductivity higher than that of the semiconductor substrate. In this way, heat generated in a heat generating portion can be swiftly and uniformly conducted over the entire temperature detection element composed of the diode 7 with efficiency. In this way, a semiconductor device capable of detecting temperature with excellent response by the temperature detection element and its manufacturing method can be provided.

### INCORPORATION BY REFERENCE

This application is based upon and claims the benefit of priority from Japanese patent application No. 2009-215270, filed on Sep. 17, 2009, the disclosure of which is incorporated herein in its entirety by reference.

### BACKGROUND

1. Field of the Invention

The present invention relates to a semiconductor device and its manufacturing method, in particular a semiconductor device including a temperature detection element and its manufacturing method.

2. Description of Related Art

Semiconductor devices such as power MOSFETs (Metal-Oxide-Semiconductor Field-Effect Transistors) in which a large current flows are equipped with a built-in diode(s) as a temperature detection element in order to protect the semiconductor devices from abnormal heat generation (e.g., Japanese Unexamined Patent Application Publication No. 07-153920 (Patent document 1) and 2008-235600 (Patent document 2)). This feature uses the fact that the forward current-voltage characteristic of a diode exhibits temperature dependence. Therefore, to perform abnormal detection with excellent response, it is desired to swiftly conduct the heat from a portion where heat is generated to the diode with efficiency.

FIGS. 8A and 8B shows an example of a semiconductor device in related art. In particular, FIG. 8A shows a cross-section and a plane view of a semiconductor device in related art. The semiconductor device shown in FIGS. 8A and 8B is disclosed in Patent document 1, and is a power MOSFET including a temperature detection diode composed of polysilicon on the chip surface. FIGS. 8A and 8B show a cross-section of the main part and a plane view of the chip respectively.

In FIG. 8A, an N⁺-type silicon substrate 1, P⁺-type layers 2a and 2b, an N⁺-type source layer 3, a gate layer 4 composed of polysilicon, oxide films 5a and 5b, a PSG (PhosphoSilicate Glass) film 6, a temperature detection diode 7 composed of polysilicon, a P-type polysilicon layer 7a, an N-type polysilicon layer 7b, an anode electrode 8a, a cathode electrode 8b, a source electrode 9s, a drain electrode 9d, a gate electrode 9g, and a power MOSFET chip 10 are illustrated.

As shown in FIG. 8A, a FET area in which a FET is formed on the chip surface layer and a diode area in which the diode 7 is formed on the chip surface are provided on the power MOSFET chip 10. The diode 7 is composed of polysilicon and is used to detect the temperature of the chip.

In the FET area, the P⁺-type layer 2a is provided as a channel layer in a predetermined area of the N⁺-type silicon substrate 1. Further, the N⁺-type source layer 3 is provided on its surface layer.

Further, the gate layer 4 composed of polysilicon is provided on the surface of the N⁺-type silicon substrate 1 with a gate oxide film (oxide film 5a) interposed therebetween, and it is covered with the oxide film 5b and the PSG film 6.

Further, the source electrode 9s is connected to the P⁺-type layer 2a and the N⁺-type source layer 3. Note that the gate electrode 9g is connected to the gate layer 4 at a portion that is not illustrated in the figure. Further, the drain electrode 9d is formed on the rear surface of the N⁺-type silicon substrate 1.

Meanwhile, in the diode area, the temperature detection diode 7 is provided on the P⁺-type layer 2b, which is an inactive area, with the oxide film 5a interposed therebetween.

The temperature detection diode 7 is formed by the PN junction of the P-type polysilicon layer 7a and the N-type polysilicon layer 7b. The temperature detection diode 7 is covered with the oxide film 5b and the PSG film 6.

Further, the P-type polysilicon layer 7a and the N-type polysilicon layer 7b are connected to the anode electrode 8a and the cathode electrode 8b, respectively, through openings formed in the oxide film 5b and the PSG film 6.

Note that as shown in FIG. 8B, the source electrode 9s, the gate electrode 9g, the diode 7, the anode electrode 8a, and the cathode electrode 8b are disposed on the chip surface.

In the MOSFET chip 10 like this, the temperature of the chip is detected based on the forward voltage drop of the temperature detection diode 7 by using the dependence of the forward voltage drop on the temperature. Further, when the temperature rises to or above a predetermined temperature, the current flowing through the MOSFET is controlled in order to prevent the thermal destruction.

Next, FIGS. 9A and 9B shows another semiconductor device in related art. In particular, FIG. 9A shows a cross-section and a plane view of another semiconductor device in related art. The semiconductor device shown in FIGS. 9A and 9B is disclosed in Patent document 2, and is an IGBT (Insulated Gate Bipolar Transistor) in which a temperature detection diode composed of polysilicon is disposed within a trench formed in the chip surface layer. FIGS. 9A and 9B show, respectively, a cross-section of the main part of an IGBT and a plane view of a part of the IGBT indicated by the line IXB-IXB in FIG. 9A.

In FIGS. 9A and 9B, an N⁺-type emitter area 12, a gate electrode 14, an emitter electrode 16, a gate insulating film 17, a p-type base area 18, trenches 19 and 50, an insulating film 20, an n-type drift area 21, an N⁺-type buffer area 24, P⁺-type collector area 28, a collector electrode 30, an insulating film 60, a P⁺-type base contact area 80, a temperature detection diode 504, a p-type polysilicon layer 504a, an n-type polysilicon layer 504b, and an IGBT chip 500 are illustrated.

In this IGBT chip 500, each of the trenches is filled with the p-type polysilicon layer 504a and the n-type polysilicon layer 504b from the bottom to the surface.

That is, the temperature detection diode 504 composed of polysilicon is disposed in such a manner that the temperature detection diode 504 is embedded inside the trench 50 with the insulating film 60 interposed therebetween in an attempt to improve the temperature detection capability.

### SUMMARY

As described above, in the MOSFET chip 10 of Patent document 1 shown in FIGS. 8A and 8B, the temperature detection diode 7 is disposed on the chip surface. Further, in the IGBT chip 500 of Patent document 2 shown in FIGS. 9A and 9B, the temperature detection diode 504 is disposed inside a trench.

These temperature detection diodes 7 and 504 are disposed in the vicinity of an FET area, which is the main heat generating portion, so that abnormal heat generation can be detected more quickly.

However, simply giving consideration to the place of the temperature detection diode cannot provide a satisfactory result in a scheme to conduct heat swiftly from the heat generating portion (FET area) to the temperature detection diode with efficiency. The reason for this is explained hereinafter.

FIGS. 10A and 10B schematically shows an aspect of thermal conduction to a temperature detection diode in a semiconductor device in related art. In particular, FIG. 10A shows a cross-section of the MOSFET chip 10 corresponding to FIG. 8A, and FIG. 10B is an enlarged plane view of the IGBT chip 500 obtained by enlarging the temperature detection diode 504 and its peripheral area shown in FIG. 9B.

As shown in FIGS. 10A and 10B, heat generated in the FET area is conducted to the temperature detection diode 7 or 504 mainly through the silicon substrate and/or the silicon oxide film in the semiconductor device in the related art. However, the silicon substrate (thermal conductivity: about 170 W/m·K) and the silicon oxide film (thermal conductivity: about 1.3 W/m·K) do not have excellent thermal conductivity. Further, since the actual place of the FET area at which the abnormal heat generation occurs is uncertain, the direction from which the heat is conducted to the temperature detection diode 7 or 504 cannot be specified. From these facts, in the case where the heat is conducted along the longitudinal direction of the temperature detection diode 7 or 504, for example, as indicated by arrows with broken lines in FIGS. 10A and 10B, a considerable difference in thermal conduction occurs between the nearest portion and the farthest portion. As a result, the temperature hardly rises uniformly over the entire diode, thus making the temperature detection with excellent response impossible.

A first exemplary aspect of the present invention is a semiconductor device including: a temperature detection element to detect abnormal heat generation, the temperature detection element being formed on a semiconductor substrate; and a thermal conduction layer having a thermal conductivity higher than that of the semiconductor substrate, the thermal conduction layer being formed between the temperature detection element and the semiconductor substrate. With the structure like this, heat generated in the heat generating portion can be swiftly and uniformly conducted over the entire temperature detection element with efficiency.

Further, another exemplary aspect of the present invention is a method of manufacturing a semiconductor device including: forming, on an semiconductor substrate, a thermal conduction layer having a thermal conductivity higher than that of the semiconductor substrate; forming an insulating film on the thermal conduction layer; and forming a temperature detection element to detect abnormal heat generation on a surface that faces the thermal conduction layer through the insulation layer. As a result, heat generated in the heat generating portion can be swiftly and uniformly conducted over the entire temperature detection element with efficiency.

The present invention can provide a semiconductor device capable of detecting temperature with excellent response by a temperature detection element, and its manufacturing method. The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1A shows a structure of a semiconductor device in accordance with a first exemplary embodiment of the present invention;

FIG. 1B shows a structure of a semiconductor device in accordance with a first exemplary embodiment of the present invention;

FIG. 2A is a schematic diagram for explaining an aspect of thermal conduction to a temperature detection diode in a semiconductor device in accordance with a first exemplary embodiment in a step-by-step manner;

FIG. 2B is a schematic diagram for explaining an aspect of thermal conduction to a temperature detection diode in a semiconductor device in accordance with a first exemplary embodiment in a step-by-step manner;

FIG. 3A is cross-sections showing a manufacturing process of a semiconductor device in accordance with a first exemplary embodiment;

FIG. 3B is cross-sections showing a manufacturing process of a semiconductor device in accordance with a first exemplary embodiment;

FIG. 3C is cross-sections showing a manufacturing process of a semiconductor device in accordance with a first exemplary embodiment;

FIG. 3D is cross-sections showing a manufacturing process of a semiconductor device in accordance with a first exemplary embodiment;

FIG. 3E is cross-sections showing a manufacturing process of a semiconductor device in accordance with a first exemplary embodiment;

FIG. 3F is cross-sections showing a manufacturing process of a semiconductor device in accordance with a first exemplary embodiment;

FIG. 3G is cross-sections showing a manufacturing process of a semiconductor device in accordance with a first exemplary embodiment;

FIG. 3H is cross-sections showing a manufacturing process of a semiconductor device in accordance with a first exemplary embodiment;

FIG. 4 is a cross-section in a step of a manufacturing process of a semiconductor device in accordance with another first exemplary embodiment;

FIG. 5A shows a structure of a semiconductor device in accordance with a second exemplary embodiment of the present invention;

FIG. 5B shows a structure of a semiconductor device in accordance with a second exemplary embodiment of the present invention;

FIG. 6A is cross-sections showing a manufacturing process of a semiconductor device in accordance with a second exemplary embodiment;

FIG. 6B is cross-sections showing a manufacturing process of a semiconductor device in accordance with a second exemplary embodiment;

FIG. 6C is cross-sections showing a manufacturing process of a semiconductor device in accordance with a second exemplary embodiment;

FIG. 6D is cross-sections showing a manufacturing process of a semiconductor device in accordance with a second exemplary embodiment;

FIG. 6E is cross-sections showing a manufacturing process of a semiconductor device in accordance with a second exemplary embodiment;

FIG. 6F is cross-sections showing a manufacturing process of a semiconductor device in accordance with a second exemplary embodiment;

FIG. 6G is cross-sections showing a manufacturing process of a semiconductor device in accordance with a second exemplary embodiment;

FIG. 6H is cross-sections showing a manufacturing process of a semiconductor device in accordance with a second exemplary embodiment;

FIG. 6I is cross-sections showing a manufacturing process of a semiconductor device in accordance with a second exemplary embodiment;

FIG. 7 is a cross-section in a step of a manufacturing process of a semiconductor device in accordance with another second exemplary embodiment;

FIG. 8A is a cross-section and a plane view of a semiconductor device in related art;

FIG. 8B is a cross-section and a plane view of a semiconductor device in related art;

FIG. 9A is a cross-section and a plane view of another semiconductor device in related art;

FIG. 9B is a cross-section and a plane view of another semiconductor device in related art;

FIG. 10A is a diagram schematically showing an observation of thermal conduction to a temperature detection diode in a semiconductor device in related art; and

FIG. 10B is a diagram schematically showing an observation of thermal conduction to a temperature detection diode in a semiconductor device in related art.

### DETAILED DESCRIPTION OF THE EXEMPLARY EMBODIMENTS

Exemplary embodiments of the present invention are explained hereinafter with reference to the drawings. For clarifying the explanation, the following description and the drawings may be partially omitted or simplified as appropriate. Further, duplicated explanation may be also omitted as appropriate for clarifying the explanation. Note that similar components are denoted by the same signs throughout the drawings, and duplicated explanation may be omitted as appropriate.

### First Exemplary Embodiment

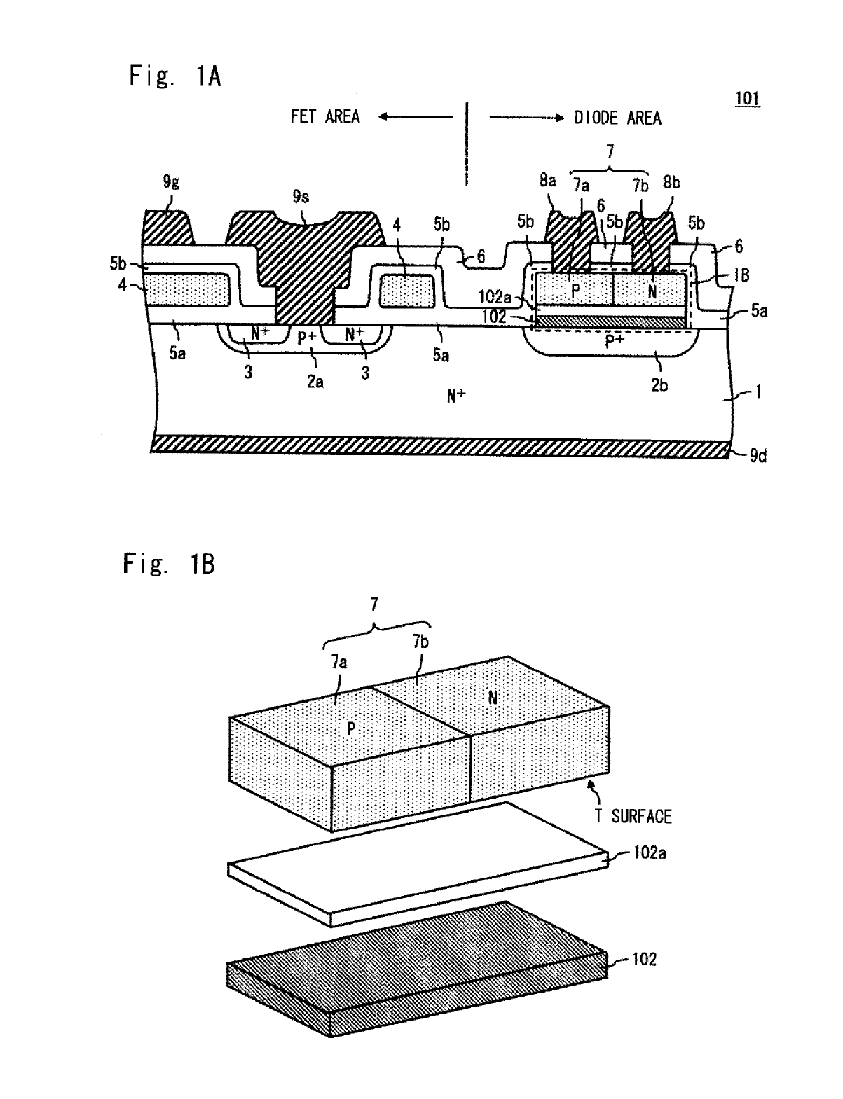

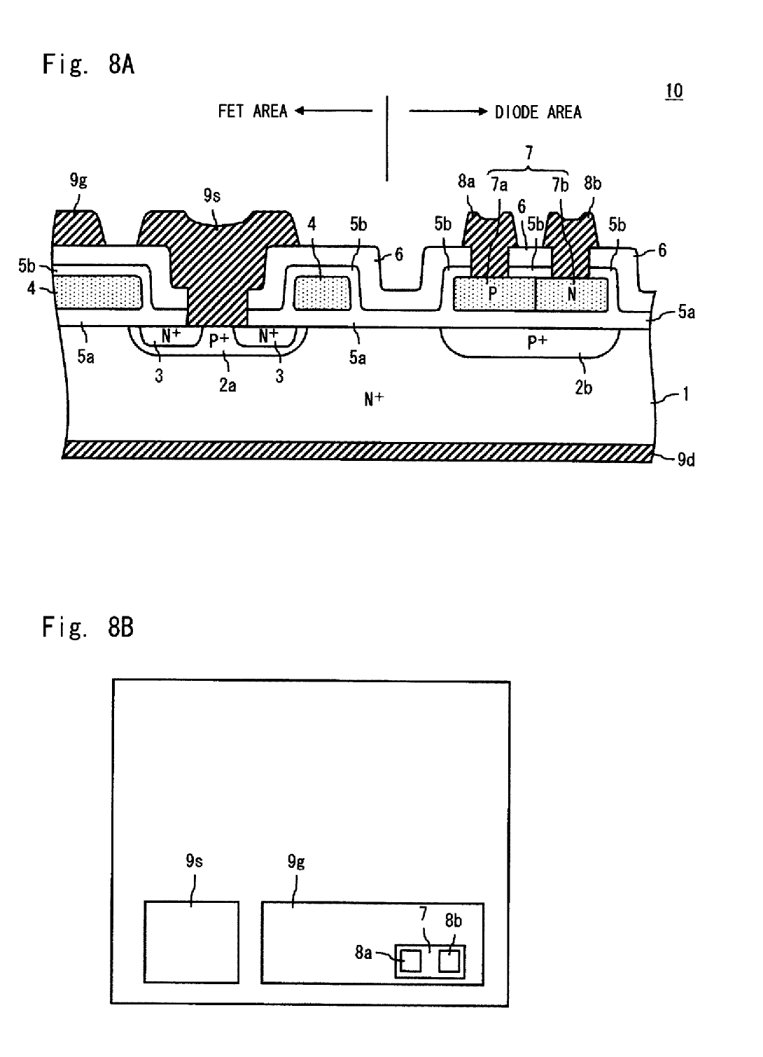

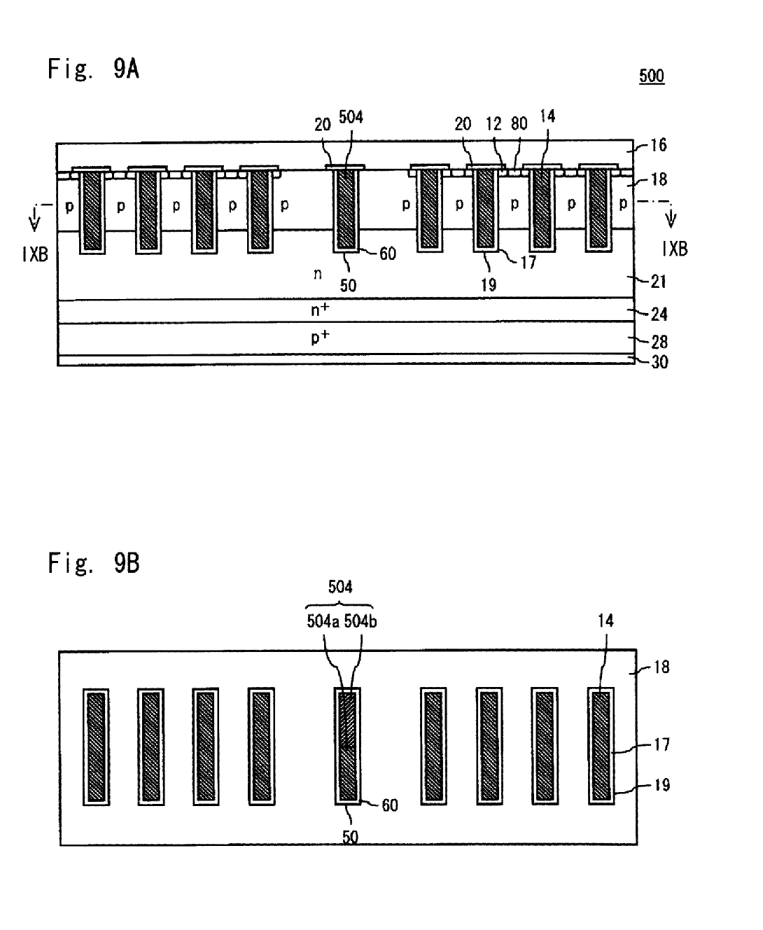

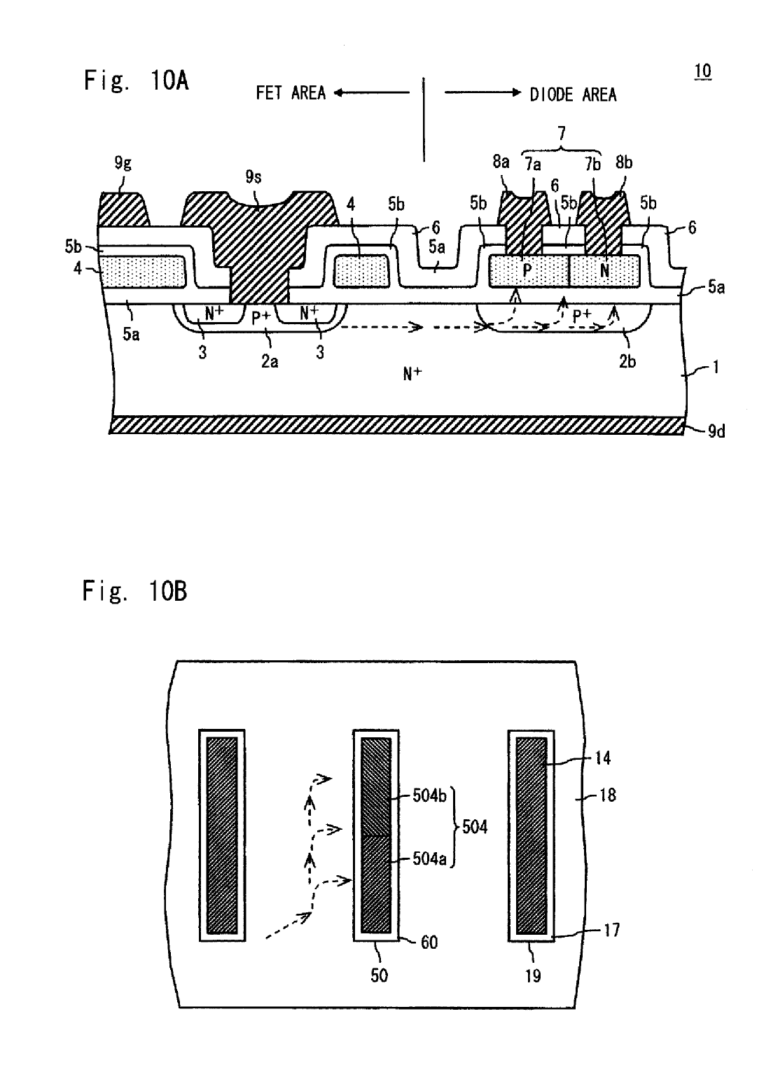

A semiconductor device in accordance with this exemplary embodiment of the present invention is explained hereinafter with reference to FIGS. 1A, 1B. FIGS. 1A, 1B shows a structure of a semiconductor device in accordance with a first exemplary embodiment of the present invention. The semiconductor device in accordance with this exemplary embodiment is a power MOSFET in which a temperature detection diode composed of polysilicon (hereinafter, simply called “diode”) is disposed on the surface of the semiconductor substrate. FIGS. 1(a) and 1(b) show, respectively, a cross-section of the main part of the semiconductor device in accordance with this exemplary embodiment and an exploded perspective view of the IB portion shown in FIG. 1A. Note that the same components as those of FIGS. 8A, 8b are denoted by the same signs, and their detailed explanation is omitted.

Similarly to the power MOSFET chip 10 in the related art in FIG. 8b, a FET area in which a FET is formed on the chip surface layer and a diode area in which a diode 7 is formed on the chip surface are provided on a power MOSFET chip 101 as shown in FIG. 1A. The diode 7 is composed of polysilicon and is used to detect the temperature of the chip. In this exemplary embodiment, although the structure of the diode area is different from that of the power MOSFET chip 10 in the related art, the structure of the FET area is similar to that of the power MOSFET chip 10.

Specifically, similarly to the FET area of the power MOSFET chip 10 in the related art, in the FET area of the power MOSFET chip 101, a P⁺-type layer 2a is provided as a channel layer in a predetermined area of an N⁺-type silicon substrate 1, which is a semiconductor substrate. Further, an N⁺-type source layer 3 is provided on its surface layer. Further, a gate layer 4 composed of polysilicon is provided on the surface of the N⁺-type silicon substrate 1 with a gate oxide film (oxide film 5a) interposed therebetween, and it is covered with an oxide film 5b and a PSG film 6. Furthermore, a source electrode 9s is connected to the P⁺-type layer 2a and the N⁺-type source layer 3. Note that a gate electrode 9g is connected to the gate layer 4 at a portion that is not illustrated in the figure. Further, a drain electrode 9d is formed on the rear surface of the N⁺-type silicon substrate 1.

Meanwhile, in the diode area, a P⁺-type layer 2b, which is an inactive area, is formed on the surface layer of the N⁺-type silicon substrate 1, which is a semiconductor substrate. A diode 7, which serves as a temperature detection element, is provided on this P⁺-type layer 2b with a thermal conduction layer 102 and an insulating film 102a interposed therebetween. That is, while the oxide film 5a is sandwiched between the silicon substrate 1 and the diode 7 in the power MOSFET chip 10, the stacked film that is formed by stacking the insulating film 102a on the thermal conduction layer 102 is sandwiched, instead of the oxide film 5a, in the power MOSFET chip 101 in accordance with this exemplary embodiment of the present invention.

The thermal conduction layer 102 is disposed on the P⁺-type layer 2b formed in the surface layer of the silicon substrate 1. The thermal conduction layer 102 is formed from material having a thermal conductivity higher than that of the silicon constituting the semiconductor substrate (thermal conductivity: about 170 W/m·K). In this example, for example, an aluminum film (thermal conductivity: 237 W/m·K) is formed as the thermal conduction layer 102. Note that when the thermal conduction layer 102 is formed from an aluminum film, silicon is preferably contained in this aluminum film. By forming the thermal conduction layer 102 from an aluminum film containing silicon, the aluminum spike can be suppressed.

The insulating film 102a is formed on the surface of the thermal conduction layer 102. That is, as shown in FIG. 1B, the thermal conduction layer 102 is disposed between the thermal conduction layer 102 and the diode 7. The thermal conduction layer 102 is electrically isolated from the diode 7 by this insulating film 102a. The insulating film 102a is preferably formed from material having a thermal conductivity higher than that of the silicon oxide film. In this way, faster thermal conduction to the diode 7 becomes possible.

In this example, the insulating film 102a is formed by an alumina (Al₂O₃) film that is an oxide film of the aluminum film formed as the thermal conduction layer 102. The alumina film (thermal conductivity: about 30 W/m·K) has a thermal conductivity about 20 times higher than that of the silicon oxide film (thermal conductivity: about 1.3 W/m·K), and thus enabling the heat generated in the thermal conduction layer 102 to be swiftly conducted to the diode 7.

Further, the diode 7 is disposed on the insulating film 102a. The diode 7 constitutes a PN-junction diode in which a P-type polysilicon layer 7a and an N-type polysilicon layer 7b are arranged in parallel in the horizontal direction. The diode 7 is disposed so as to be opposed to the thermal conduction layer 102 through the insulating film 102a.

Similarly to the power MOSFET chip 10 in the related art in FIGS. 8A, 8B, the diode 7 is covered with an oxide film 5b and a PSG (PhosphoSilicate Glass) film 6. Further, the P-type polysilicon layer 7a and the N-type polysilicon layer 7b are connected to an anode electrode 8a and a cathode electrode 8b, respectively, through openings formed in the oxide film 5b and the PSG film 6.

In this way, the power MOSFET chip 101 in accordance with this exemplary embodiment is different from the power MOSFET chip 10 in the related art in that the thermal conduction layer 102 and the insulating film 102a are disposed between the semiconductor substrate composed of the N⁺-type silicon substrate 1 and the diode 7.

In the power MOSFET chip 101 having the structure like this, the temperature of the chip is detected based on the forward voltage drop of the diode 7 by using the dependence of the forward voltage drop on the temperature. Further, when the temperature rises to or above a predetermined temperature, the current flowing through the MOSFET is controlled in order to prevent the thermal destruction.

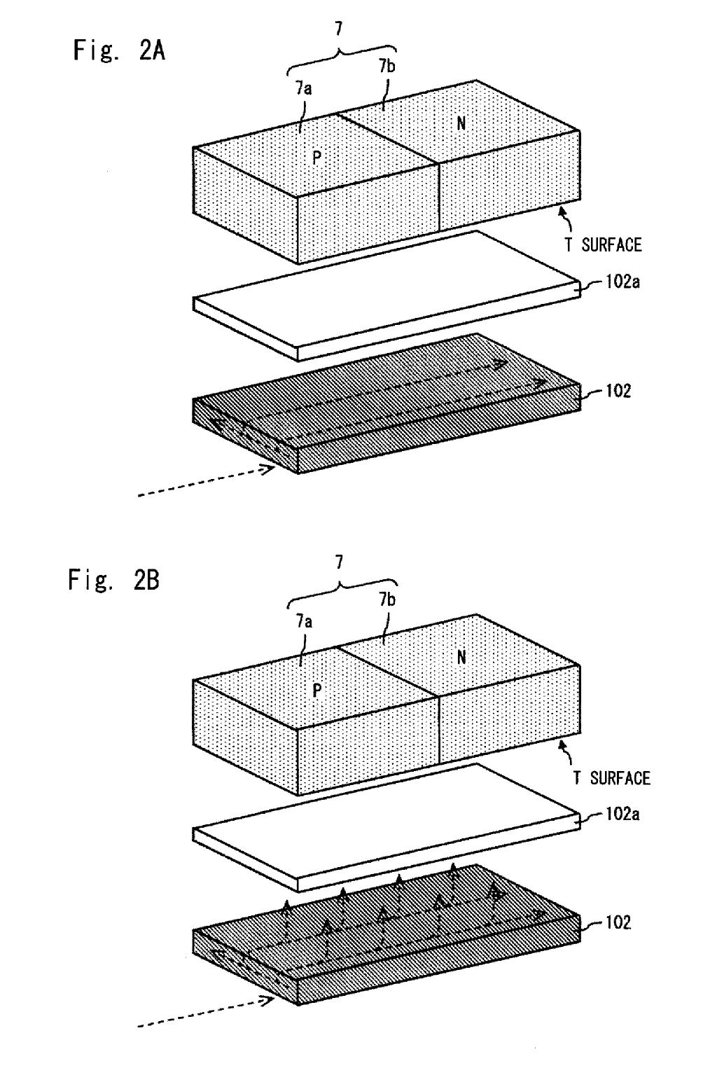

An aspect of thermal conduction to the temperature detection diode 7 disposed in the above-described fashion is explained hereinafter with reference to FIGS. 2A, 2B. FIGS. 2A, 2B is a schematic diagram for explaining an aspect of thermal conduction to a temperature detection diode in a semiconductor device of the first exemplary embodiment in a step-by-step manner.

The thermal conduction layer 102 disposed between the semiconductor substrate and the diode 7 has a high thermal conductivity. Therefore, when heat generated in the FET area reaches the thermal conduction layer 102 from an unspecified direction, the heat is swiftly propagated over the entire thermal conduction layer 102 as shown in FIG. 2A. Then, as shown in FIG. 2B, the heat propagated over the entire thermal conduction layer 102 is uniformly conducted toward the under surface (T surface) of the diode 7, which is disposed so as to face the thermal conduction layer 102. As a result, it becomes possible to detect the temperature with excellent response by the diode 7. Further, the diode 7 can be designed without giving much consideration to its longitudinal size, thus improving the flexibility in the designing. In this way, in the semiconductor device in accordance with this exemplary embodiment, the thermal conduction layer 102 serves to swiftly spread and propagate the heat that has arrived at the thermal conduction layer 102 from an unspecified direction over the entire thermal conduction layer 102.

As shown in FIGS. 1A, 1B, the shape of the thermal conduction layer 102 as viewed from the top is preferably roughly the same shape as that of the under surface (T surface) of the diode 7. That is, the thermal conduction layer 102 and the diode 7 preferably have roughly the same shape in their mutually opposed surfaces. By making their opposed surfaces roughly the same shape, it is possible to conduct heart uniformly over the entire diode 7 with efficiency.

If the thermal conduction layer 102 is considerably smaller than the under surface of the diode 7 or has a lot of portions that do not conform to the shape of the under surface of the diode 7, a lot of portions at which they are not opposed are created. As a result, the efficiency in the thermal conduction between them deteriorates.

On the other hand, if the thermal conduction layer 102 is considerably larger than the under surface of the diode 7 or has a lot of portions that do not conform to the shape of the under surface of the diode 7, a lot of portions at which they are not opposed are created. As a result, the amount of the heat that is radiated to components other than the diode 7 increases, thus deteriorating the efficiency in the thermal conduction between them.

Note that although an example where the shape of the under surface (T surface) of the diode 7 and the shape of the thermal conduction layer 102 as viewed from the top are the same elongated rectangle is shown with reference to FIGS. 1 and 2, their shapes are not limited to this example. That is, the shape of the under surface of the diode 7 and the shape of the thermal conduction layer 102 as viewed from the top may be shapes other than the elongated rectangle, provided that they are roughly the same shape.

That is, the thermal conduction layer 102 in accordance with this exemplary embodiment has the following structural difference from the power MOSFET chip 10 in the related art with regard to the disposition of the diode 7: (1) The thermal conduction layer 102 composed of an aluminum film, which has roughly the same shape as the under surface of the diode 7 and has a thermal conductivity higher than that of the silicon substrate 1, is disposed so as to be opposed to the diode 7; and (2) The insulating film 102a such as an alumina film having a thermal conductivity higher than that of the silicon oxide film is disposed, instead of the silicon oxide film, as an insulating film between the diode 7 and the silicon substrate 1. With these features (1) and (2), the power MOSFET chip 101 in accordance with this exemplary embodiment of the present invention has a superior thermal conduction to the diode 7 to that of the power MOSFET chip 10 in the related art, and heat generated in the heat generating portion can be swiftly and uniformly conducted over the entire diode 7 with efficiency. Therefore, in the power MOSFET chip 101 in accordance with this exemplary embodiment, it is possible to detect the temperature with more excellent response in comparison to the power MOSFET chip 10 in the related art.

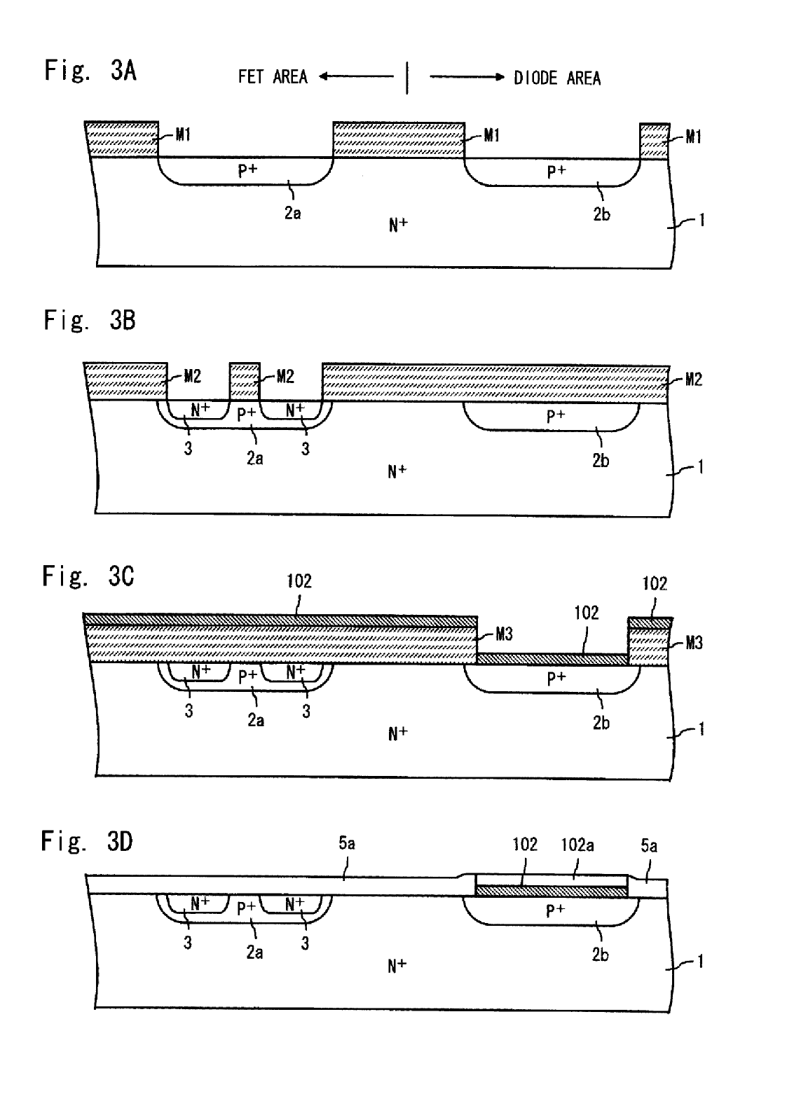

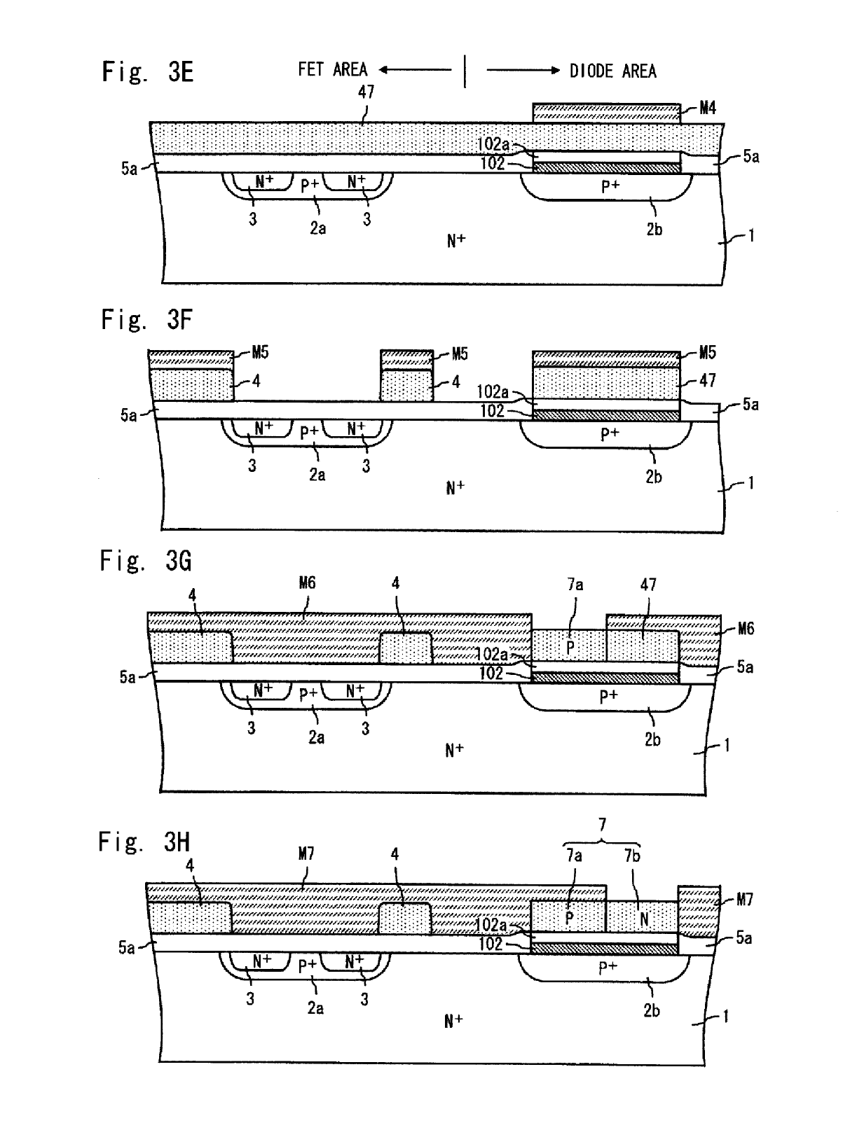

Next, an example of a manufacturing method of a power MOSFET chip 101 having the above-described structure is explained hereinafter with reference to FIGS. 3A to 3H. FIGS. 3A to 3H are cross-sections showing a manufacturing process of a semiconductor device in accordance with a first exemplary embodiment of the present invention. A case where a thermal conduction layer 102 is formed by using a lift-off method is explained hereinafter as an example.

Firstly, as shown in FIG. 3A, a resist mask M1 having a predetermined pattern is formed on an N⁺-type silicon substrate 1. After that, ions of a P-type impurity are implanted and heat treatment is carried out to form P⁺-type layers 2a and 2b.

Next, after removing the resist mask M1, a resist mask M2 having a predetermined pattern is formed as shown in FIG. 3B. After that, ions of an N-type impurity are implanted and heat treatment is carried out to form an N⁺-type source layer 3.

Next, after removing the resist mask M2, a thermal conduction layer 102 is formed by using a lift-off method. Specifically, firstly, a resist mask M3 having a predetermined pattern is formed on the silicon substrate 1 as shown in FIG. 3C. An aluminum (Al) layer is formed as a thermal conduction layer 102 on this resist mask M3 by vapor deposition or sputtering. As a result, the thermal conduction layer 102 is formed on the resist mask M3 and on the part of the silicon substrate 1 that is not covered by the resist mask M3, and a structure shown in FIG. 3C is thereby obtained. Next, the resist mask M3 and the part of the thermal conduction layer 102 that is located on the resist mask M3 are removed. As a result, only the portion of the thermal conduction layer 102 that is disposed on the silicon substrate 1 without the resist mask M3 interposed therebetween remains.

Note that the resist mask M3 is formed in advance in the predetermined place so that the remaining thermal conduction layer 102 is located directly below the diode 7 that is formed in a later step, which is described later.

Further, the resist mask M3 is formed in advance in a predetermined shape so that the shape of the remaining thermal conduction layer 102 as viewed from the top is roughly the same as the under surface of the diode 7 that is formed in the later step described later.

Note that when aluminum is used as the material of the thermal conduction layer 102, silicon is preferably contained in the aluminum so that aluminum spike can be suppressed.

After the thermal conduction layer 102 is formed on the P⁺-type layer 2b of the silicon substrate 1 in this manner, an oxide film is formed over the entire surface of the silicon substrate 1 by a thermal oxidation method.

As a result, as shown in FIG. 3D, a silicon oxide (SiO₂) film is formed as an oxide film 5a on the surface of the silicon substrate 1, and an alumina (Al₂O₃) film is formed as an insulating film 102a on the surface of the thermal conduction layer 102 composed of aluminum.

The oxide film 5a serves as a gate insulating film, and the insulating film 102a serves to electrically isolate the thermal conduction layer 102 from the diode 7 that is formed in a later step described later.

Next, a polysilicon layer 47 is deposited to a predetermined thickness on the entire surface by a CVD method. After the part of the polysilicon layer 47 that is located in the diode area is covered with a resist mask M4, an N-type impurity is implanted to lower the resistance of the part of the polysilicon layer 47 that is located in the FET area. As a result, a structure shown in FIG. 3E is obtained. Note that since the part of the polysilicon layer 47 located in the diode area is covered with the resist mask M4, it remains as non-doped polysilicon because no N-type impurity is implanted there.

Next, after the resist mask M4 is removed, a resist mask M5 having a pattern covering a predetermined area of the polysilicon layer 47 is formed. In this example, the resist mask M5 is formed in each of the areas that will become the gate layer 4 and the diode 7 respectively on the polysilicon layer 47.

Then, dry etching is carried out on the polysilicon layer 47 by using this resist mask M5. As a result, the polysilicon layer 47 is patterned into a desired shape, and the gate layer 4 and the pattern of the polysilicon layer 47 that will become the diode 7 in a later step are simultaneously formed as shown in FIG. 3F.

Next, after the resist mask M5 is removed, a resist mask M6 is formed such that the part of the polysilicon layer 47 that will become the diode 7 is exposed as shown in FIG. 3G. The resist mask M6 has such a pattern shape that the part of the polysilicon layer 47 that is located in the diode area is divided into two sections and one of the sections is opened. In this example, as shown in FIG. 3G, a pattern in which the part that will become the P-type polysilicon layer 7a is opened is formed as the resist mask M6. Then, a P-type impurity is implanted by using this resist mask M6 to form the P-type polysilicon layer 7a.

Next, after the resist mask M6 is removed, a resist mask M7 in which the area that will become the N-type polysilicon layer 7b is opened as opposed to the resist mask M6 is formed as shown in FIG. 3H. Then, an N-type impurity is implanted by using this resist mask M7 to form the N-type polysilicon layer 7b. By these steps, the diode 7 composed of polysilicon (PN-junction diode) is formed.

Next, after the resist mask M7 is removed, an anneal process is carried out to activate the impunities.

Next, an oxide film 5b is formed over the entire surface by a CVD method. Further, a PSG film 6 is deposited over the entire surface of the oxide film 5b by a CVD method.

Next, after a resist mask having a predetermined pattern (not shown) is formed, openings are formed through the PSG film 6 and the oxide films 5a and 5b by dry etching. Then, a source electrode 9s, a gate electrode 9g, an anode electrode 8a, and a cathode electrode 8b are formed on the front-surface side of the silicon substrate 1 by vapor deposition, sputtering, or the like. After that, a drain electrode 9d is formed on the rear surface of the silicon substrate 1 by vapor deposition or sputtering. The manufacturing of a power MOSFET chip 101 in accordance with this exemplary embodiment shown in FIG. 1A has been completed through the steps described above.

Note that although an example where the thermal conduction layer 102 is formed by using a lift-off method is explained in the above explanation, the formation method of the thermal conduction layer 102 is not limited to this example. That is, the thermal conduction layer 102 may be formed by using a photo lithography method or an etching method.

Further, although the insulating film 102a is formed by the thermal oxidation method in the above explanation, it may be formed by using a CVD method or a PVD method.

Furthermore, although an example where aluminum is used as the material used to form the thermal conduction layer 102 is explained in the above explanation, the present invention is not limited to this example. That is, any material having a thermal conductivity higher than that of the silicon substrate 1 may be used for that purpose.

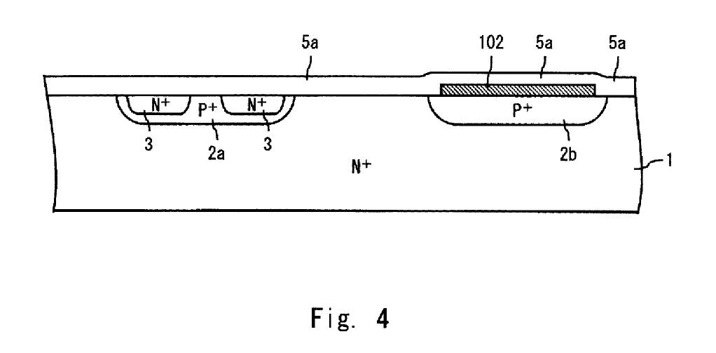

FIG. 4 is a cross-section in a step of a manufacturing process of a semiconductor device in accordance with another first exemplary embodiment. FIG. 4 shows a manufacturing step corresponding to FIG. 3D. For example, for the thermal conduction layer 102, gold (Au) (thermal conductivity: 315 W/m·K), copper (Cu) (thermal conductivity: 398 W/m·K), and the like may be also used as the material having a high thermal conductivity.

However, when gold and/or copper is used, an excellent surface oxide film cannot be formed by the thermal oxidation method in contrast to the case where aluminum is used. Therefore, in such a case, after a thermal conduction layer 102 having a predetermined pattern shape composed of a gold film or a copper film is formed, an oxide film 5a composed of a silicon oxide film is preferably formed over the entire surface of the silicon substrate 1 by a CVD method. In this way, a structure shown in FIG. 4 in which the thermal conduction layer 102 is covered with the oxide film 5a is obtained. As described above, the semiconductor device may have such a structure that the oxide film 5a, which is different from the insulating film 102a composed of an oxide film of the thermal conduction layer 102, extends from the area on the silicon substrate 1 to the area between the thermal conduction layer 102 and the diode 7. The thermal conduction layer 102 is electrically isolated from the diode 7 by this oxide film 5a. Even in the structure like this, since the thermal conduction layer 102, which has roughly the same shape as the under surface of the diode 7 and is composed of material having a thermal conductivity higher than that of the semiconductor substrate, is disposed so as to be opposed to the diode 7, heat generated in the heat generating portion can be swiftly and uniformly conducted over the entire diode 7 with efficiency.

As has been described above, in this exemplary embodiment of the present invention, the thermal conduction layer 102 composed of material having a thermal conductivity higher than that of the semiconductor substrate is disposed between the temperature detection element (diode 7) and the semiconductor substrate (silicon substrate 1). In this way, heat generated in the heat generating portion can be swiftly conducted over the entire temperature detection element with efficiency. As a result, it is possible to realize temperature detection with excellent response by a temperature detection element.

### Second Exemplary Embodiment

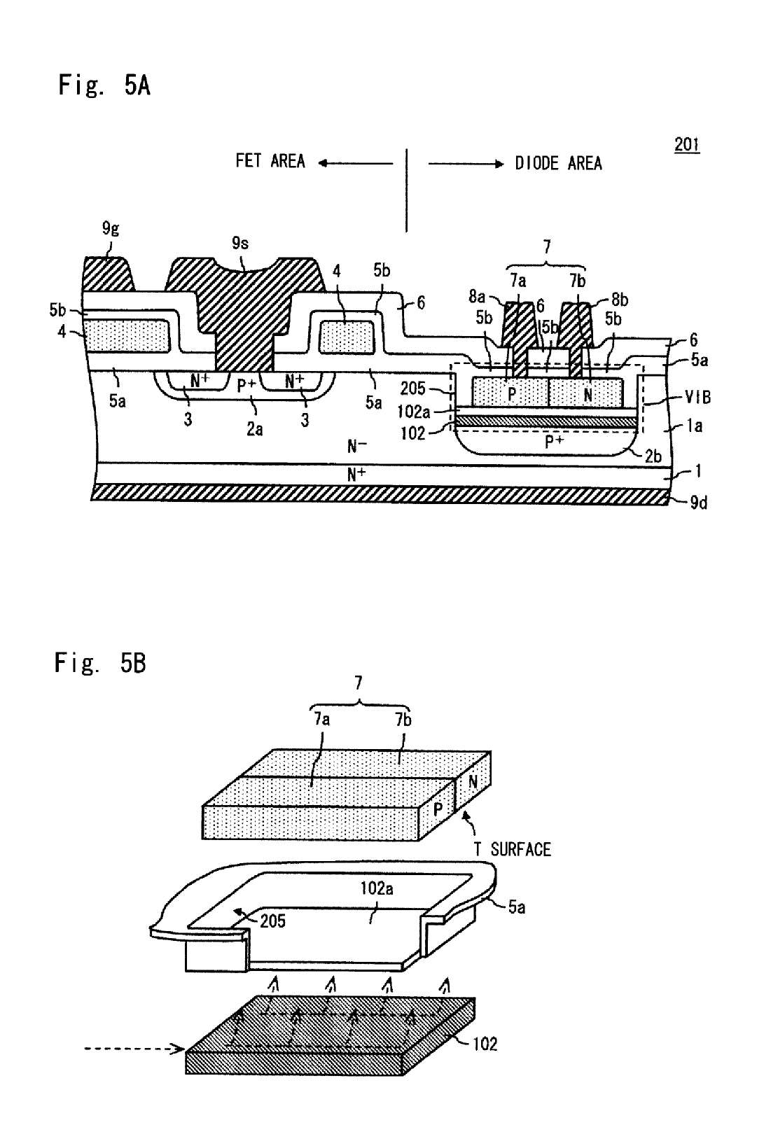

A semiconductor device in accordance with this exemplary embodiment of the present invention is explained hereinafter with reference to FIGS. 5A, 5B. FIGS. 5A, 5B shows a structure of a semiconductor device in accordance with a second exemplary embodiment of the present invention. The semiconductor device in accordance with this exemplary embodiment is a power MOSFET in which a temperature detection diode composed of polysilicon is disposed inside a concave portion formed in the surface layer of the semiconductor substrate. FIGS. 5A and 5B show, respectively, a cross-section of the main part of the semiconductor device in accordance with this exemplary embodiment and an exploded perspective view of the VIB portion shown in FIG. 5A. Note that the same portions as those of FIG. 1A, 1B are denoted by the same signs, and their detailed explanation is omitted.

A FET area in which a FET is formed on the chip surface layer and a diode area in which a diode 7 is formed are provided on a power MOSFET chip 201 as shown in FIG. 5B. The diode 7 is composed of polysilicon and is used to detect the temperature of the chip. In this exemplary embodiment, although the structure of the diode area is different from that of the first exemplary embodiment, the structure of the FET area is similar to that of the first exemplary embodiment. Therefore, the explanation of the FET area is omitted here. Note that in the power MOSFET chip 201 in accordance with this exemplary embodiment, an N⁻-type epitaxial layer 1a is stacked on an N⁺-type silicon substrate 1, and these N⁺-type silicon substrate 1 and N⁻-type epitaxial layer 1a constitute a semiconductor substrate. A P⁺-type layer 2a, which will become a channel layer, is provided in the surface layer of this semiconductor substrate.

In this exemplary embodiment, a concave portion 205 is formed in the diode area on the surface of the semiconductor substrate. The concave portion 205 is formed in the N⁻-type epitaxial layer 1a of the semiconductor substrate. For example, the shape of the concave portion 205 as viewed from the top may be an elongated rectangle as shown in FIG. 5B. Further, a P⁺-type layer 2b, which is an inactive area, is formed in the surface layer of the part of the N⁻-type epitaxial layer 1a in which the concave portion 205 is formed.

Furthermore, in this exemplary embodiment, the thermal conduction layer 102 is disposed on the bottom surface of the concave portion 205. Similarly to the first exemplary embodiment, the thermal conduction layer 102 is formed from material having a thermal conductivity higher than that of the silicon constituting the semiconductor substrate. In this example, for example, an aluminum film is formed as the thermal conduction layer 102. Note that when the thermal conduction layer 102 is formed from an aluminum film, silicon is preferably contained in this aluminum film. By forming the thermal conduction layer 102 from an aluminum film containing silicon, the aluminum spike can be suppressed.

Then, similarly to the first exemplary embodiment, an insulating film 102a that is an oxide film of the thermal conduction layer 102 is formed on the surface of the thermal conduction layer 102, and the diode 7 is disposed on the insulating film 102a. That is, the insulating film 102a is disposed between the thermal conduction layer 102 and the diode 7. The thermal conduction layer 102 is electrically isolated from the diode 7 by this insulating film 102a.

In this example, the insulating film 102a is formed by an alumina film, which is an oxide film of the aluminum film formed as the thermal conduction layer 102. The alumina film has a thermal conductivity about 20 times higher than that of the silicon oxide film, and thus enabling the heat generated in the thermal conduction layer 102 to be swiftly conducted to the diode 7. As described above, the insulating film 102a is preferably formed from material having a thermal conductivity higher than that of the silicon oxide film.

Similarly to the first exemplary embodiment, the diode 7 is covered with an oxide film 5b and a PSG (PhosphoSilicate Glass) film 6. Further, the P-type polysilicon layer 7a and the N-type polysilicon layer 7b are connected to an anode electrode 8a and a cathode electrode 8b, respectively, through openings formed in the oxide film 5b and the PSG film 6.

As described above, the power MOSFET chip 201 in accordance with this exemplary embodiment is different from the power MOSFET chip 101 of the first exemplary embodiment in that the diode 7 of the power MOSFET chip 201 is disposed inside the concave portion 205 formed in the substrate surface layer.

In the power MOSFET chip 201 having the structure like this, the temperature of the chip is detected based on the forward voltage drop of the diode 7 by using the dependence of the forward voltage drop on the temperature. Further, when the temperature rises to or above a predetermined temperature, the current flowing through the MOSFET is controlled in order to prevent the thermal destruction.

Note that the thermal conduction layer 102 disposed between the semiconductor substrate and the diode 7 has a high thermal conductivity. Therefore, when heat generated in the FET area reaches the thermal conduction layer 102 from an unspecified direction as shown in FIG. 5B, the heat is swiftly propagated over the entire thermal conduction layer 102. Then, the heat propagated over the entire thermal conduction layer 102 is uniformly conducted toward the under surface (T surface) of the diode 7, which is disposed so as to face the thermal conduction layer 102. As a result, it becomes possible to detect the temperature with excellent response by the diode 7.

Further, the diode 7 can be designed without giving much consideration to its longitudinal size, thus improving the flexibility in the designing. In this way, in the semiconductor device in accordance with this exemplary embodiment, the thermal conduction layer 102 serves to swiftly spread and propagate the heat that has arrived at the thermal conduction layer 102 from an unspecified direction over the entire thermal conduction layer 102. Further, since the diode 7 is disposed inside the concave portion 205 in this exemplary embodiment, the temperature detection capability can be improved even further compared to the first exemplary embodiment.

As shown in FIGS. 5A, 5B, the shape of the thermal conduction layer 102 as viewed from the top is preferably roughly the same shape as that of the under surface (T surface) of the diode 7. That is, the thermal conduction layer 102 and the diode 7 preferably have roughly the same shape in their mutually opposed surfaces. By making their opposed surfaces roughly the same shape, it is possible to conduct heart uniformly over the entire diode 7 with efficiency.

Strictly speaking, the size of the under surface of the diode 7 is somewhat smaller than that of the shape of the thermal conduction layer 102 as viewed from the top by an amount equivalent to the thickness of the oxide film 5a formed on the sidewall of the concave portion 205. However, the shape difference at such a level does not substantially deteriorate the thermal conductivity between them, and is considered to be a level that does not cause any substantial problem.

Note that although an example where the shape of the under surface (T surface) of the diode 7 and the shape of the thermal conduction layer 102 as viewed from the top are the same elongated rectangle is shown with reference to FIGS. 5A, 5B, their shapes are not limited to this example. That is, the shape of the under surface of the diode 7 and the shape of the thermal conduction layer 102 as viewed from the top may be shapes other than the elongated rectangle, provided that they are roughly the same shape.

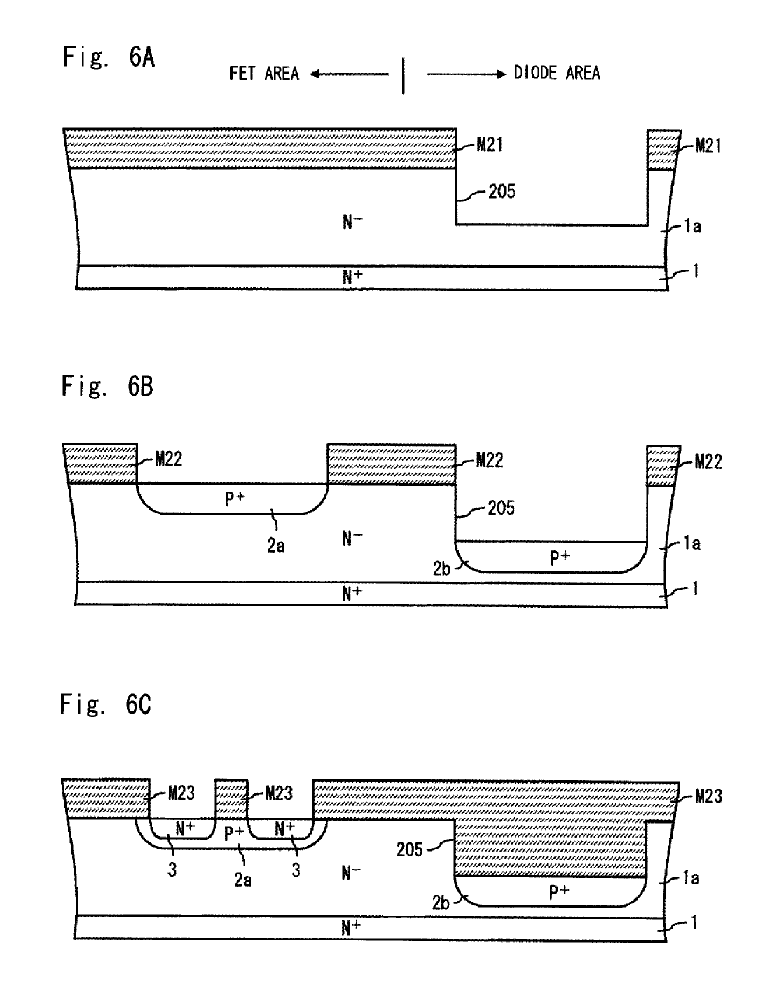

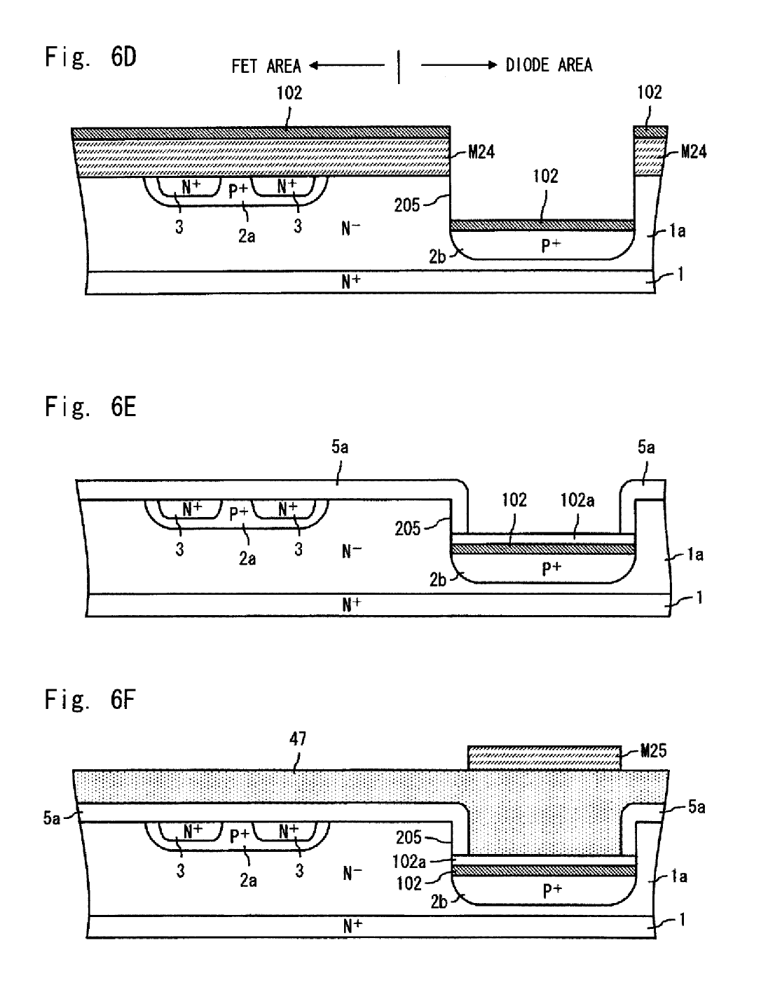

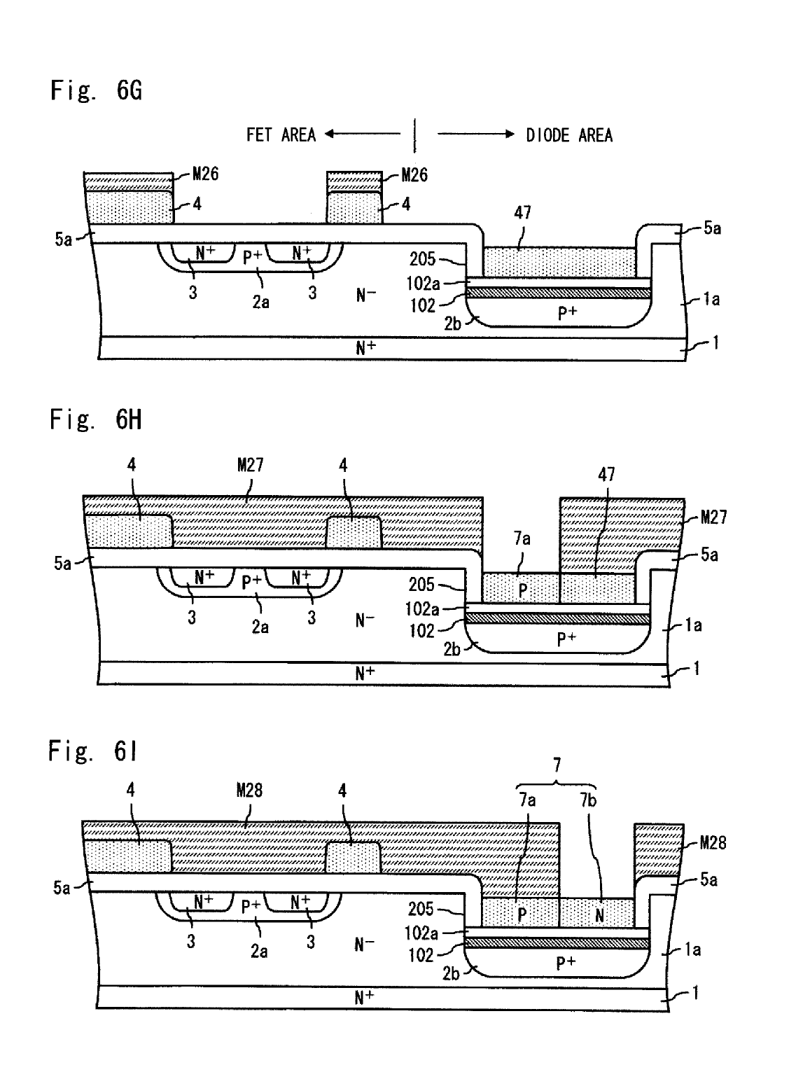

Next, an example of a manufacturing method of a power MOSFET chip 201 having the above-described structure is explained hereinafter with reference to FIGS. 6A to 6I. FIGS. 6A to 6I are cross-sections showing a manufacturing process of a semiconductor device in accordance with a second exemplary embodiment of the present invention. A case where a thermal conduction layer 102 is formed by using a lift-off method is explained hereinafter as an example.

Firstly, as shown in FIG. 6A, a resist mask M21 having a predetermined pattern is formed on an N⁻-type epitaxial layer 1a that has been grown on an N⁺-type silicon substrate 1. Then, by performing silicon etching (dry etching) using this resist mask M21, a concave portion 205 is formed in the N⁻-type epitaxial layer 1a. The shape of the concave portion 205 as viewed from the top is, for example, an elongated rectangular.

Next, after removing the resist mask M21, a resist mask M22 having a predetermined pattern is formed as shown in FIG. 6B. Then, ions of a P-type impurity are implanted by using this resist mask M22 to form P⁺-type layers 2a and 2b on the N⁻-type epitaxial layer 1a.

Next, after removing the resist mask M22, a resist mask M23 having a predetermined pattern is formed as shown in FIG. 6C. Then, ions of an N-type impurity are implanted by using this resist mask M23 to form an N⁺-type source layer 3 in the surface layer of the P⁺-type layer 2a.

Next, after removing the resist mask M23, a thermal conduction layer 102 is formed by using a lift-off method. Specifically, firstly, a resist mask M24 having a predetermined pattern is formed as shown in FIG. 6D. An aluminum (Al) layer is formed as a thermal conduction layer 102 on this resist mask M24 by vapor deposition or sputtering. As a result, the thermal conduction layer 102 is formed on the resist mask M24 and on the part of the N⁻-type epitaxial layer 1a that is not covered by the resist mask M24, and a structure shown in FIG. 6D is thereby obtained. Next, the resist mask M24 and the part of the thermal conduction layer 102 that is located on the resist mask M24 are removed, so that only the portion of the thermal conduction layer 102 that is disposed on the N⁻-type epitaxial layer 1a without the resist mask M24 interposed therebetween remains.

Note that the resist mask M24 is formed in advance in the predetermined place so that the remaining thermal conduction layer 102 is located directly below the temperature detection diode 7 that is formed in a later step, which is described later. Further, the resist mask M24 is formed in advance in a predetermined shape so that the shape of the remaining thermal conduction layer 102 as viewed from the top is roughly the same as the under surface of the temperature detection diode 7 that is formed in the later step described later. In this way, the thermal conduction layer 102 is formed on the bottom surface of the concave portion 205.

Note that when aluminum is used as the material of the thermal conduction layer 102, silicon is preferably contained in the aluminum so that aluminum spike can be suppressed.

After the thermal conduction layer 102 is formed on the P⁺-type layer 2b of the N⁻-type epitaxial layer 1a in this manner, an oxide film is formed over the entire surface of the semiconductor substrate by a thermal oxidation method.

As a result, as shown in FIG. 6E, a silicon oxide (SiO₂) film is formed as an oxide film 5a on the surface of the N⁻-type epitaxial layer 1a, and an alumina (Al₂O₃) film is formed as an insulating film 102a on the surface of the thermal conduction layer 102 composed of aluminum.

The oxide film 5a serves as a gate insulating film, and the insulating film 102a serves to electrically isolate the thermal conduction layer 102 from the diode 7 that is formed in a later step described later.

Next, a polysilicon layer 47 is deposited to a predetermined thickness on the entire surface by a CVD method. After the part of the polysilicon layer 47 that is located in the diode area is covered with a resist mask M25, an N-type impurity is implanted to lower the resistance of the part of the polysilicon layer 47 that is located in the FET area. As a result, a structure shown in FIG. 6F is obtained. Note that since the part of the polysilicon layer 47 located in the diode area is covered with the resist mask M25, it remains as non-doped polysilicon because no N-type impurity is implanted there.

Next, after the resist mask M25 is removed, a resist mask M26 having a pattern covering a predetermined area of the polysilicon layer 47 is formed. In this example, the resist mask M26 is formed in the area of the polysilicon layer 47 that will become the gate layer 4. Note that in this exemplary embodiment, the resist mask M26 does not necessarily have to be formed in the area of the polysilicon layer 47 that will become the diode 7 in contrast to the first exemplary embodiment.

Then, dry etching is carried out on the polysilicon layer 47 by using this resist mask M26. By this dry etching, the polysilicon layer 47 on the concave portion 205 is reduced in film-thickness. The dry etching is carried out until the part of the polysilicon layer 47 that is located outside the concave portion 205 and is not covered with the resist mask M26 is completely removed and the part of polysilicon layer 47 that is located inside the concave portion 205 is thinned to a desired thickness. As a result, the polysilicon layer 47 is patterned into a desired shape, and the gate layer 4 and the pattern of the polysilicon layer 47 that will become the diode 7 inside the concave portion 205 are simultaneously formed as shown in FIG. 6G.

Next, after the resist mask M26 is removed, a resist mask M27 is formed such that the part of the polysilicon layer 47 that will become the diode 7 is exposed as shown in FIG. 6H. The resist mask M27 has such a pattern shape that the part of the polysilicon layer 47 that is located in the diode area is divided into two sections and one of the sections is opened. In this example, as shown in FIG. 6H, a pattern in which the part that will become the P-type polysilicon layer 7a is opened is formed as the resist mask M27. Then, a P-type impurity is implanted by using this resist mask M27 to form the P-type polysilicon layer 7a.

Next, after the resist mask M27 is removed, a resist mask M28 in which the area that will become the N-type polysilicon layer 7b is opened as opposed to the resist mask M27 is formed as shown in FIG. 6I. Then, an N-type impurity is implanted by using this resist mask M28 to form the N-type polysilicon layer 7b. By these steps, the diode 7 composed of polysilicon (PN-junction diode) is formed.

Next, after the resist mask M28 is removed, an anneal process is carried out to activate the impunities.

Next, an oxide film 5b is formed over the entire surface by a CVD method. Further, a PSG film 6 is deposited over the entire surface of the oxide film 5b by a CVD method.

Next, after a resist mask having a predetermined pattern (not shown) is formed, openings are formed through the PSG film 6 and the oxide films 5a and 5b by dry etching. Then, a source electrode 9s, a gate electrode 9g, an anode electrode 8a, and a cathode electrode 8b are formed on the front-surface side of the semiconductor substrate by vapor deposition, sputtering, or the like. After that, a drain electrode 9d is formed on the rear surface of the semiconductor substrate by vapor deposition or sputtering. The manufacturing of a power MOSFET chip 201 in accordance with this exemplary embodiment shown in FIG. 5A has been completed through the steps described above.

Note that although an example where the thermal conduction layer 102 is formed by using a lift-off method is explained in the above explanation, the formation method of the thermal conduction layer 102 is not limited to this example. That is, the thermal conduction layer 102 may be formed by using a photo lithography method or an etching method.

Further, although the insulating film 102a is formed by the thermal oxidation method in the above explanation, it may be formed by using a CVD method or a PVD method.

Furthermore, although an example where aluminum is used as the material used to form the thermal conduction layer 102 is explained in the above explanation, the present invention is not limited to this example. That is, any material having a thermal conductivity higher than that of the semiconductor substrate may be used for that purpose.

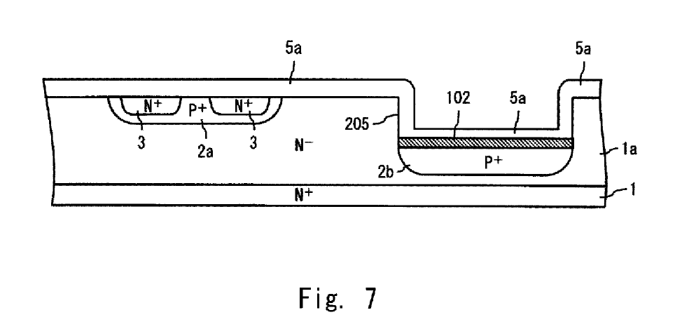

FIG. 7 is a cross-section in a step of a manufacturing process of a semiconductor device in accordance with another second exemplary embodiment. FIG. 7 shows a manufacturing step corresponding to FIG. 6E. For example, for the thermal conduction layer 102, gold (Au) (thermal conductivity: 315 W/m·K), copper (Cu) (thermal conductivity: 398 W/m·K), and the like may be also used as the material having a high thermal conductivity.

However, when gold and/or copper is used, an excellent surface oxide film cannot be formed by the thermal oxidation method in contrast to the case where aluminum is used. Therefore, in such a case, after a thermal conduction layer 102 having a predetermined pattern shape composed of a gold film or a copper film is formed, an oxide film 5a composed of a silicon oxide film is preferably formed over the entire surface of the semiconductor substrate by a CVD method. In this way, a structure shown in FIG. 7 in which the thermal conduction layer 102 is covered with the oxide film 5a is obtained. As described above, the semiconductor device may have such a structure that the oxide film 5a, which is different from the insulating film 102a composed of an oxide film of the thermal conduction layer 102, extends from the area on the N⁻-type epitaxial layer 1a to the area between the thermal conduction layer 102 and the diode 7. The thermal conduction layer 102 is electrically isolated from the diode 7 by this oxide film 5a. Even in the structure like this, since the thermal conduction layer 102, which has roughly the same shape as the under surface of the diode 7 and is composed of material having a thermal conductivity higher than that of the semiconductor substrate, is disposed so as to be opposed to the diode 7, heat generated in the heat generating portion can be swiftly and uniformly conducted over the entire diode 7 with efficiency.

As has been described above, the diode 7 is disposed inside the concave portion 205 in this exemplary embodiment of the present invention, and by doing so, the temperature detection capability can be improved even further compared to the first exemplary embodiment. Further, similarly to the first exemplary embodiment, the thermal conduction layer 102 composed of material having a thermal conductivity higher than that of the semiconductor substrate is disposed between the temperature detection element (diode 7) and the semiconductor substrate (silicon substrate 1 and N⁻-type epitaxial layer 1a) in this exemplary embodiment of the present invention. In this way, heat generated in the heat generating portion can be swiftly conducted over the entire temperature detection element with efficiency. As a result, it is possible to realize temperature detection with excellent response by a temperature detection element.

Note that the present invention is not limited to the above-described exemplary embodiments, and various modifications can be made without departing from the spirit and scope of the present invention.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor device comprising:
a temperature detection element to detect abnormal heat generation, in a semiconductor substrate; and
a thermal conduction layer having a thermal conductivity higher than that of the semiconductor substrate, the thermal conduction layer being formed between the temperature detection element and the semiconductor substrate.

2. The semiconductor device according to claim 1, further comprising an insulating film formed between the thermal conduction layer and the temperature detection element,
wherein the temperature detection element is electrically isolated from the thermal conduction layer by the insulating film.

3. The semiconductor device according to claim 2, wherein
the thermal conduction layer is formed from a metal film comprising at least one of aluminum, gold and copper.

4. The semiconductor device according to claim 3, wherein
the insulating film is formed from an alumina film.

5. The semiconductor device according to claim 3, wherein the metal film comprising aluminum further comprises silicon.

6. The semiconductor device according to claim 3, wherein
the insulating film is formed from a silicon oxide film.

7. The semiconductor device according to claim 1, wherein
the thermal conduction layer is disposed so as to face the temperature detection element, and
the thermal conduction layer and the temperature detection element have roughly a same shape in their mutually opposed surfaces.

8. The semiconductor device according to claim 1, wherein the temperature detection element is disposed above a top surface plane of the semiconductor substrate.

9. The semiconductor device according to claim 1, wherein the temperature detection element is disposed inside a concave portion formed in the semiconductor substrate.

10. A method of manufacturing a semiconductor device comprising:
forming, on a semiconductor substrate, a thermal conduction layer having a thermal conductivity higher than that of the semiconductor substrate;
forming an insulating film on the thermal conduction layer; and
forming a temperature detection element to detect abnormal heat generation on a surface that faces the thermal conduction layer through the insulation layer.
